(19) United States
(12) Patent Application Publication
(10) Pub. No.: US 2003/0062600 A1
(43) Pub. Date: Apr. 3, 2003

(54) Process for optimizing mechanical strength of nanoporous silica

(76) Inventors: Hui-Jung Wu, Fremont, CA (US); James S. Drage, Fremont, CA (US); Teresa Ramos, Albuquerque, NM (US); Douglas M. Smith, Albuquerque, NM (US); Stephen Wallace, Albuquerque, NM (US); Kevin Roderick, Albuquerque, NM (US); Lisa Beth Brungardt, Albuquerque, NM (US)

Correspondence Address: ROBERTS & MERCANTI, LLP, P.O. BOX 484, PRINCETON, NJ, 08542-0484, US

(21) Appl. No.: 10/260,871

(22) Filed: Sep. 30, 2002

Related U.S. Application Data
(62) Division of application No. 09/141,287, filed on Aug. 27, 1998.

(51) Int. Cl. H01L 23/58; H01L 21/31; H01L 21/469

(52) U.S. Cl. 257/632; 438/778; 438/780; 438/781; 257/642

(57) ABSTRACT

A process for forming a nanoporous dielectric coating on a substrate. The process includes forming a substantially uniform alkoxysilane gel composition on a surface of a substrate, which alkoxysilane gel composition comprises a combination of at least one alkoxysilane, an organic solvent composition, water, and an optional base catalyst; heating the substrate for a sufficient time and at a sufficient temperature in an organic solvent vapor atmosphere to thereby condense the gel composition; and then curing the gel composition to form a nanoporous dielectric coating having high mechanical strength on the substrate.

### BACKGROUND OF THE INVENTION

1. Field of the Invention

The invention relates to nanoporous dielectric films and to a process for their manufacture. Such films are useful in the production of integrated circuits.

2. Description of the Prior Art

In the production of integrated circuits, the problems of interconnect RC delay, power consumption and crosstalk become more significant as feature sizes approach 0.25 μm and below. It has been found that the use of low dielectric constant (K) materials for interlevel dielectric and intermetal dielectric applications partially mitigate these problems. However, each of the material candidates which are under consideration by the industry, having dielectric constants significantly lower than the currently employed dense silica, suffer from disadvantages. Most low dielectric constant materials developments use spin-on-glasses and fluorinated plasma chemical vapor disposition SiO₂ with K of >3. Some organic and inorganic polymers have dielectric constants in the range of about 2.2 to 3.5, however, these have the problems of low thermal stability, poor mechanical properties including low glass transition temperature, sample outgassing, and long term reliability questions.

One solution is the use of nanoporous silica as porous substrate, interlevel and intermetal dielectrics and, which have dielectric constants in the range of about 1 to 3. Nanoporous silica films are typically formed on substrates by methods such as dip-coating or spin-coating. Nanoporous silica is particularly attractive due to the ability to carefully control its pore size and pore distribution, and because it employs similar precursors such as tetraethoxysilane (TEOS), as is presently used for spin-on glass (SOG's), and CVD SiO₂. In addition to having low dielectric constants, nanoporous silica offers other advantages for microelectronics, including thermal stability up to 900° C.; small pore size (<<microelectronics features); use of materials, namely silica and its precursors, that are widely used in the semiconductor industry; the ability to tune dielectric constant over a wide range; and deposition using similar tools as employed for conventional spin-on glass processing. EP patent application EP 0 775 669 A2, which is incorporated herein by reference, shows a method for producing a nanoporous silica film with uniform density throughout the film thickness.

A key parameter controlling property of importance for nanoporous silica dielectrics is porosity, the inverse of density. Higher porosity materials lead to a lower dielectric constant than dense materials. As porosity increases, density and dielectric constant decrease. However, the mechanical strength of the material decreases as well. Mechanical strength is essential for the production of integral circuits. During the fabrication of integral circuits, many layers of metal conductors and insulating dielectric films are deposited on a substrate. These layers must be able to endure multiple temperature changes at very high temperatures. This temperature cycling can produce high stress levels between the individual layers of the integral circuits due to thermal coefficient of expansion mismatches. Inadequate mechanical strength of any one of the layers can lead to cracking or delamination, which results in poor yield. In addition to temperature cycling, mechanical strength is essential for chemical mechanical polishing of the layers. Poor mechanical strength causes degradation of the nanoporous film and its layers during polishing steps. Clearly, a method is needed for producing a nanoporous film of adequate mechanical strength and low K to be used for producing adequate integral circuits.

The present invention offers a solution to this problem. It has been unexpectedly found that heating a wet alkoxysilane gel composition in an organic solvent vapor atmosphere after deposition onto a substrate results in a nanoporous dielectric film of higher mechanical strength and lower K. According to the present invention, a wet alkoxysilane gel composition is formed on a suitable substrate and is placed in an organic solvent vapor atmosphere. The gel composition, having extremely low mechanical strength, is then aged by heating in the solvent vapor atmosphere. The solvent vapor atmosphere prevents the gel composition from drying during heating. After heating, the aged alkoxysilane gel composition of this invention is then cured or dried. Using this process, a relatively uniform nanoporous silica film is produced having optimal mechanical strength and a low K.

### SUMMARY OF THE INVENTION

The invention provides a process for forming a nanoporous dielectric coating on a substrate which comprises:

(a) forming a substantially uniform alkoxysilane gel composition on a surface of a substrate, which alkoxysilane gel composition comprises a combination of at least one alkoxysilane, an organic solvent composition, water, and an optional base catalyst;

(b) heating the substrate for a sufficient time and at a sufficient temperature in an organic solvent vapor atmosphere to thereby condense the gel composition; and then

(c) curing the gel composition to form a nanoporous dielectric coating on the substrate.

This invention still further provides a semiconductor device produced by the above process wherein the substrate is a semiconductor substrate.

### DETAILED DESCRIPTION OF THE PREFERRED EMBODIMENT

According to the invention, an alkoxysilane gel composition is formed on a surface of a substrate from at least one alkoxysilane, an organic solvent composition, water, and an optional base catalyst.

The alkoxysilane gel composition may be formed on the surface of a substrate in a variety of ways. In one embodiment, the alkoxysilane gel composition is formed by depositing a pre-formed mixture of an alkoxysilane, an organic solvent composition, water, and an optional base catalyst onto a surface of a substrate. In another embodiment, a combined stream of alkoxysilane, organic solvent composition, and optional base catalyst is deposited onto the substrate and then exposed to water. In another embodiment, a combined stream is exposed to water before deposition onto the substrate. In still another embodiment, a combined stream is simultaneously exposed to water and deposited onto the substrate. The water can be in the form of a water stream or a water vapor atmosphere. After a combining of the alkoxysilane, organic solvent composition, water, and optional base catalyst and deposition onto the substrate, an alkoxysilane gel composition is formed on the substrate which is then subjected to an aging process by hotplate or oven heating in a solvent vapor atmosphere. Once removed from the solvent vapor atmosphere, the aged gel may be cured or dried to thereby form a nanoporous dielectric coating on the substrate having optimal mechanical strength.

Useful alkoxysilanes for this invention include those which have the formula:

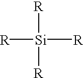

wherein at least 2 of the R groups are independently C₁ to C₄ alkoxy groups and the balance, if any, are independently selected from the group consisting of hydrogen, alkyl, phenyl, halogen, substituted phenyl. For purposes of this invention, the term alkoxy includes any other organic group which can be readily cleaved from silicon at temperatures near room temperature by hydrolysis. R groups can be ethylene glycoxy or propylene glycoxy or the like, but preferably all four R groups are methoxy, ethoxy, propoxy or butoxy. The most preferred alkoxysilanes nonexclusively include tetraethoxysilane (TEOS) and tetramethoxysilane.

The alkoxysilane component of the alkoxysilane gel composition is preferably present in an amount of from about 3% to about 50% by weight of the overall blend, more preferably from about 5% to about 45% and most preferably from about 10% to about 40%.

Preferably, the organic solvent composition comprises a relatively high volatility solvent or a relatively low volatility solvent or both a relatively high volatility solvent and a relatively low volatility solvent. The solvent, usually the higher volatility solvent, is at least partially evaporated immediately after deposition onto the substrate. This partial drying leads to better planarity due to the lower viscosity of the material after the first solvent or parts of the solvent comes off. The more volatile solvent evaporates over a period of seconds or minutes. Slightly elevated temperatures may optionally be employed to accelerate this step. Such temperatures preferably range from about 20° C. to about 80° C., more preferably from about 20° C. to about 50° C. and most preferably from about 20° C. to about 35° C.

For purposes of this invention, a relatively high volatility solvent is one which evaporates at a temperature below, preferably significantly below, that of the relatively low volatility solvent. The relatively high volatility solvent preferably has a boiling point of about 120° C. or less, more preferably about 100° C. or less. Suitable high volatility solvents nonexclusively include methanol, ethanol, n-propanol, isopropanol, n-butanol and mixtures thereof. Other relatively high volatility solvent which are compatible with the other ingredients can be readily determined by those skilled in the art.

The relatively low volatility solvent is one which evaporates at a temperature above, preferably significantly above, that of the relatively high volatility solvent. The relatively low volatility solvent preferably has a boiling point of about 175° C. or higher, more preferably about 200° C. or higher. Such preferably have the formula R₁(OR₂)ₙOH wherein R₁ is a linear or branched C₁ to C₄ alkyl group, R₂ is a C₁ to C₄ alkylene group, and n is 2-4. Preferred low volatility solvent composition components include di(ethylene)glycol monomethyl ether, tri(ethylene)glycol monomethyl ether, tetra(ethylene)glycol monomethyl ether; di(propylene)glycol monomethyl ether, tri(propylene)glycol monomethyl ether and mixtures thereof. Other suitable low volatility solvent compositions nonexclusively include alcohols and polyols including glycols such as ethylene glycol, 1,4-butylene glycol, 1,5-pentanediol, 1,2,4-butanetriol, 1,2,3-butanetriol, 2-methyl-propanetriol, 2-(hydroxymethyl)-1,3-propanediol, 1,4,1,4-butanediol, 2-methyl -1,3-propanediol, tetraethylene glycol, triethylene glycol monomethyl ether, glycerol, di(ethylene)glycol, tri(ethylene)glycol, tetra(ethylene)glycol; penta(ethylene)glycol, di(propylene)glycol, hexa(ethylene)glycol and mixtures thereof. Other relatively low volatility solvents which are compatible with the other ingredients can be readily determined by those skilled in the art.

The organic solvent component is preferably present in the alkoxysilane gel composition an amount of from about 20% to about 90% by weight of the composition, more preferably from about 30% to about 70% and most preferably from about 40% to about 60%. When both a high and a low volatility solvent are present, the high volatility solvent is preferably present in an amount of from about 20% to about 90% by weight of the alkoxysilane gel composition, more preferably from about 30% to about 70% and a most preferably from about 40% to about 60% by weight of the alkoxysilane gel composition. When both a high and a low volatility solvent are present, the low volatility solvent is preferably present in an amount of from about 1 to about 40% by weight of the alkoxysilane gel composition, more preferably from about 3% to about 30% and a most preferably from about 5% to about 20% by weight of the alkoxysilane gel composition.

Water is included in the alkoxysilane gel composition to provide a medium for hydrolyzing the alkoxysilane. The mole ratio of water to silane is preferably from about 0 to about 50, more preferably from about 0.1 to about 10 and a most preferably from about 0.5 to about 1.5. The base may be mixed with a solvent for combining with the alkoxysilane. Suitable solvents for the base include those listed above as a high volatility solvent. Most preferred solvents for use with the base are alcohols such as ethanol and isopropanol.

The optional base may be present in the alkoxysilane gel composition in a catalytic amount which can be readily determined by those skilled in the art. Preferably the molar ratio of base to silane ranges from about 0 to about 0.2, more preferably from about 0.001 to about 0.05, and most preferably from about 0.005 to about 0.02.

Suitable bases nonexclusively include ammonia and amines, such as primary, secondary and tertiary alkyl amines, aryl amines, alcohol amines and mixtures thereof which have a preferred boiling point of about 200° C. or less, more preferably 100° C. or less and most preferably 25° C. or less. Preferred amines are alcoholamines, alkylamines, methylamine, monoethanol amine, diethanol amine, triethanol amine, dimethylamine, trimethylamine, n-butylamine, n-propylamine, tetramethyl ammonium hydroxide, piperidine, 2-methoxyethylamine, mono-, di- or triethanolamines, and mono-, di-, or tri-isopropanolamines.

The ability of an amine to accept a proton in water is measured in terms of the basicity constant K_{b}, and pK_{b}=−log K_{b}. In the preferred embodiment, the pK_{b} of the base may range from about less than 0 to about 9, more preferably from about 2 to about 6 and most preferably from about 4 to about 5.

Typical substrates are those suitable to be processed into an integrated circuit or other microelectronic device. Suitable substrates for the present invention non-exclusively include semiconductor materials such as gallium arsenide (GaAs), silicon and compositions containing silicon such as crystalline silicon, polysilicon, amorphous silicon, epitaxial silicon, and silicon dioxide (SiO₂) and mixtures thereof. Lines may optionally be on the substrate surface. The lines, when present, are typically formed by well known lithographic techniques and may be composed of a metal, an oxide, a nitride or an oxynitride. Suitable materials for the lines include silica, silicon nitride, titanium nitride, tantalum nitride, aluminum, aluminum alloys, copper, copper alloys, tantalum, tungsten and silicon oxynitride. These lines form the conductors or insulators of an integrated circuit. Such are typically closely separated from one another at distances preferably of from about 20 micrometers or less, more preferably from about 1 micrometer or less, and most preferably of from about 0.05 to about 1 micrometer.

Suitable organic solvents for the vapor atmosphere include those listed above as a low volatility solvent. The organic solvent is preferably present in the solvent vapor atmosphere in an amount of from about 50% to about 99.9% saturation, more preferably from about 70% to about 99.9% saturation, and most preferably from about 90% to about 99.9% saturation. The balance of the atmosphere may be air, hydrogen, carbon dioxide, water vapor, base vapor or an inert gas such as nitrogen or argon. The coated substrate is then aged by heating the substrate for a sufficient time and at a sufficient temperature in an organic solvent vapor atmosphere to thereby condense the gel composition. Within the context of this invention, condensing means polymerizing and strengthening the coating.

To age the gel, the deposited substrate is heated in a conventional way such as placing the substrate on a hot plate within the solvent vapor atmosphere, or heating the entire solvent vapor atmosphere in an oven. Suitable heating temperatures preferably range from about 30° C. to about 200° C., more preferably from about 60° C. to about 150° C., most preferably from about 70° C. to about 100° C. The gel may optionally be partially heated with or without the solvent vapor atmosphere prior to aging.

Suitable aging time for the gel preferably ranges from about 10 seconds to about 60 minutes, more preferably from about 30 seconds to about 3 minutes, and most preferably from about 1 minute to about 2 minutes.

The aged alkoxysilane gel composition may then be cured or dried in a conventional way, i.e. outside of a solvent atmosphere. Elevated temperatures may be employed to cure or dry the coating. Such temperatures preferably range from about 20° C. to about 450° C., more preferably from about 50° C. to about 350° C. and most preferably from about 175° C. to about 320° C. For purposes of the present invention, the term “curing” refers to the curing or drying of the combined composition onto the substrate after deposition and exposure to water.

As a result, a relatively uniform, high mechanical strength, low dielectric constant nanoporous dielectric film is formed on the substrate. The nanoporous dielectric film preferably has a dielectric constant of from about 1.1 to about 3.5, more preferably from about 1.3 to about 3.0, and most preferably from about 1.5 to about 2.5. The size of the pores in the nanoporous dielectric film preferably ranges from about 1 nm to about 100 nm, more preferably from about 2 nm to about 30 nm, and most preferably from about 3 nm to about 20 nm. The density of the nanoporous dielectric film, including the pores, preferably ranges from about 0.1 to about 1.9 g/cm², more preferably from about 0.25 to about 1.6 g/cm², and most preferably from about 0.4 to about 1.2 g/cm².

In an optional additional step, the nanoporous dielectric film on the substrate may be reacted with an effective amount of a surface modification agent for a period of time sufficient for the surface modification agent to penetrate the pore structure and render it hydrophobic. The surface modification must be conducted after aging but may be conducted either before or after drying. The surface modification agent is hydrophobic and suitable for silylating silanol moieties on the hydrophilic pore surfaces. Preferably the surface modification agent is a compound having a formula selected from the group consisting of: R₃SiNHSiR₃, RₓSiCl_{y}, RₓSi(OH)_{y}, R₃SiOSiR₃, RₓSi(OR)_{y}, MₚSi(OH)_{[4-p]}, RₓSi(OCOCH₃)_{y} and combinations thereof, wherein x is an integer ranging from 1 to 3, y is an integer ranging from 1 to 3 such that y=4−x, p is an integer ranging from 2 to 3; each R is an independently selected hydrophobic organic moiety; each M is an independently selected hydrophobic organic moiety; and R and M can be the same or different. The R and M groups are preferably independently selected from the group of organic moieties consisting of alkyl, aryl and combinations thereof. The alkyl moiety is substituted or unsubstituted and is selected from the group consisting of straight alkyl, branched alkyl, cyclic alkyl and combinations thereof, and wherein said alkyl moiety ranges in size from C₁ to about C₁₈. The aryl moiety is substituted or unsubstituted and ranges in size from C₅ to about C₁₈ Preferably the surface modification agent is selected from the group consisting of acetoxytrimethylsilane, acetoxysilane, diacetoxydimethylsilane, methyltriacetoxysilane, phenyltriacetoxysilane, diphenyldiacetoxysilane, trimethylethoxysilane, trimethylmethoxysilane, 2-trimethylsiloxypent -2-ene-4-one, n-(trimethylsilyl)acetamide, 2-(trimethylsilyl) acetic acid, n-(trimethylsilyl)imidazole, trimethylsilylpropiolate, trimethylsilyl(trimethylsiloxy)-acetate, nonamethyltrisilazane, hexamethyldisilazane, hexamethyldisiloxane, trimethylsilanol, triethylsilanol, triphenylsilanol, t-butyldimethylsilanol, diphenylsilanediol and combinations thereof. Most preferably the surface modification agent is hexamethyldisilazane. The surface modification agent may be mixed with a suitable solvent such as acetone, applied to the nanoporous silica surface in the form of a vapor, and then dried.

The following nonlimiting examples serve to illustrate the invention.

### EXAMPLE 1

This example demonstrates that a low temperature hotplate treatment in a sealed chamber can yield low density uniform films. The small void space of the chamber allows for saturation of the porosity control solvent above the wafer with minimal evaporation.

A precursor was synthesized by adding 94.0 mL of tetraethoxysilane, 61.0 mL of triethylene glygol monomethylether (TriEGMME), 7.28 mL of deionized water, and 0.31 mL of 1N nitric acid together in a round bottom flask. The solution was allowed to mix vigorously then heated to ˜80° C. and refluxed for 1.5 hours to form a solution. After the solution was allowed to cool, it was stored in refrigeration at 4° C. After the solution was allowed to cool, it was diluted 50% by volume with ethanol to reduce the viscosity. The diluted precursor was filtered to 0.1 mm using a teflon filter. Approximately 2.0 ml of the precursor was deposited onto two 4 inch silicon wafers on a spin chuck, and spun at 2500 rpm for 30 seconds. The films were gelled and aged in a vacuum chamber using the following conditions: The chamber was evacuated to −20 inches of Hg. Next, 15M ammonium hydroxide was heated and equilibrated at 45° C. and dosed into the chamber to increase the pressure to −4.0 inches of Hg for 2-3 minutes. Finally, chamber was then evacuated to −20.0 inches of Hg and backfilled with nitrogen. One film was heated at elevated temperatures for 1 min. each at 175° C. and 320° C. in air. The other film was placed in a small void space chamber that had been heated and equilibrated to 45° C. The chamber contained approximately a 2 mm void space above the wafer. The film was left in the chamber for 2 minutes then removed and heated at elevated temperatures for 1 min. each at 175° and 320° C. in air. Both films were then inspected by single wavelength multiple angle ellipsometry to determine the refractive index and thickness as seen in Table 1.

TABLE 1
Results of Nanoporous Silica Thin Films

| | No low temp | 45° C. low |
|---|---|---|
| | hotplate | temp hotplate |
| Thickness (A) | 3400 | 5616 |
| Refractive index | 1.20 | 1.124 |

This example demonstrates that films treated with a low temperature hotplate shrunk less due to added strength from the heat treatment.

### EXAMPLE 2

This example demonstrates that a low temperature hotplate treatment in a sealed chamber can yield low density uniform films. The small void space of the chamber allows for saturation of the porosity control solvent above the wafer with minimal evaporation.

A precursor was synthesized by adding 94.0 mL of tetraethoxysilane, 61.0 mL of TriEGMME, 7.28 mL of deionized water, and 0.31 mL of 1N nitric acid together in a round bottom flask. The solution was allowed to mix vigorously then heated to ˜80° C. and refluxed for 1.5 hours to form a solution. After the solution was allowed to cool, it was stored in refrigeration at 4° C. After the solution was allowed to cool, it was diluted 50% by volume with ethanol to reduce the viscosity. The diluted precursor was filtered to 0.1 mm using a teflon filter. Approximately 2.0 ml of the precursor was deposited onto two 4 inch silicon wafers on a spin chuck, and spun at 2500 rpm for 30 seconds. The films were gelled and aged in a vacuum chamber using the following conditions: The chamber was evacuated to −20 inches of Hg. Next, 15M ammonium hydroxide was heated and equilibrated at 45° C. and dosed into the chamber to increase the pressure to −4.0 inches of Hg for 2-3 minutes. Finally, chamber was then evacuated to −20.0 inches of Hg and backfilled with nitrogen. One film was heated at elevated temperatures for 1 min. each at 175° C. and 320° C. in air. The other film was placed in a small void space chamber that had been heated and equilibrated to 45° C. The chamber contained approximately a 2 mm void space above the wafer. The film was left in the chamber for 1 minutes then removed and heated at elevated temperatures for 1 min. each at 175° and 320° C. in air. Both films were then inspected by single wavelength multiple angle ellipsometry to determine the refractive index and thickness as seen in Table 2.

TABLE 2
Results of Nanoporous Silica Thin Films

| | No low temp | 45° C. low |
|---|---|---|
| | hotplate | temp hotplate |
| Thickness (A) | 3400 | 4500 |
| Refractive index | 1.20 | 1.15 |

This example demonstrates that films treated with a low temperature hotplate shrunk less due to added strength from the heat treatment.

### EXAMPLE 3

This example demonstrates that a low temperature hotplate treatment in a sealed chamber can yield low density uniform films. The small void space of the chamber allows for saturation of the porosity control solvent above the wafer with minimal evaporation.

The precursor was synthesized by adding 94.0 mL of tetraethoxysilane, 61.0 mL of TriEGMME, 7.28 mL of deionized water, and 0.31 mL of 1N nitric acid together in a round bottom flask. The solution was allowed to mix vigorously then heated to ˜80° C. and refluxed for 1.5 hours to form a solution. After the solution was allowed to cool, it was stored in refrigeration at 4° C. After the solution was allowed to cool, it was diluted 50% by volume with ethanol to reduce the viscosity. The diluted precursor was filtered to 0.1 mm using a teflon filter. Approximately 2.0 ml of the precursor was deposited onto two 4 inch silicon wafers on a spin chuck, and spun at 2500 rpm for 30 seconds. The films were gelled and aged in a vacuum chamber using the following conditions: 1) The chamber was evacuated to −20 inches of Hg. Next, 15M ammonium hydroxide was heated and equilibrated at 45° C. and dosed into the chamber to increase the pressure to −4.0 inches of Hg for 2-3 minutes. Finally, chamber was then evacuated to −20.0 inches of Hg and backfilled with nitrogen. One film was heated at elevated temperatures for 1 min. each at 175° C. and 320° C. in air. The other film was placed in a small void space chamber that had been heated and equilibrated to 50° C. The chamber contained approximately a 2 mm void space above the wafer. The film was left in the chamber for 2 minutes then removed and heated at elevated temperatures for 1 min. each at 175° and 320° C. in air. Both films were then inspected by single wavelength multiple angle ellipsometry to determine the refractive index and thickness as seen in Table 3.

TABLE 3
Results of Nanoporous Silica Thin Films

| | No low temp | 45° C. low |
|---|---|---|
| | hotplate | temp hotplate |
| Thickness (A) | 3400 | 4900 |
| Refractive index | 1.20 | 1.14 |

This example demonstrates that films treated with a low temperature hotplate shrunk less due to added strength from the heat treatment.

### EXAMPLE 4

This example demonstrates that a low temperature hotplate treatment in a open hotplate can yield fairly low density uniform films. The low volatility of the porosity control solvent allows the film to be heated at a low temperature on an open hotplate with some evaporation as well as achieving added mechanical strength to reduce film shrinkage.

A precursor was synthesized by adding 94.0 mL of tetraethoxysilane, 61.0 mL of TriEGMME, 7.28 mL of deionized water, and 0.31 mL of 1N nitric acid together in a round bottom flask. The solution was allowed to mix vigorously then heated to ˜80° C. and refluxed for 1.5 hours to form a solution. After the solution was allowed to cool, it was stored in refrigeration at 4° C. After the solution was allowed to cool, it was diluted 50% by volume with ethanol to reduce the viscosity. The diluted precursor was filtered to 0.1 mm using a teflon filter. Approximately 2.0 ml of the precursor was deposited onto two 4 inch silicon wafers on a spin chuck, and spun at 2500 rpm for 30 seconds. The films were gelled and aged in a vacuum chamber using the following conditions: The chamber was evacuated to −20 inches of Hg. Next, 15M ammonium hydroxide was heated and equilibrated at 45° C. and dosed into the chamber to increase the pressure to −4.0 inches of Hg for 2-3 minutes. Finally, chamber was then evacuated to −20.0 inches of Hg and backfilled with nitrogen. One film was heated at elevated temperatures for 1 min. each at 175° C. and 320° C. in air. The other film was placed in a open hotplate that had been heated and equilibrated to 45° C. The film was left in the chamber for 2 minutes then removed and heated at elevated temperatures for 1 min. each at 175° and 320° C. in air. Both films were then inspected by single wavelength multiple angle ellipsometry to determine the refractive index and thickness as seen in Table 4.

TABLE 4
Results of Nanoporous Silica Thin Films

| | No low temp | 45° C. low |
|---|---|---|
| | hotplate | temp hotplate |
| Thickness (A) | 3400 | 3900 |
| Refractive index | 1.20 | 1.165 |

This example demonstrates that films treated with a low temperature hotplate shrunk less due to added strength from the heat treatment.

### EXAMPLE 5

This example demonstrates that a low temperature hotplate treatment in a open hotplate can yield fairly low density uniform films. The low volatility of the porosity control solvent allows the film to be heated at a low temperature on an open hotplate with some evaporation as well as achieving added mechanical strength to reduce film shrinkage.

A precursor was synthesized by adding 94.0 mL of tetraethoxysilane, 61.0 mL of TriEGMME, 7.28 mL of deionized water, and 0.31 mL of 1N nitric acid together in a round bottom flask. The solution was allowed to mix vigorously then heated to ˜80° C. and refluxed for 1.5 hours to form a solution. After the solution was allowed to cool, it was stored in refrigeration at 4° C. After the solution was allowed to cool, it was diluted 50% by volume with ethanol to reduce the viscosity. The diluted precursor was filtered to 0.1 mm using a teflon filter. Approximately 2.0 ml of the precursor was deposited onto two 4 inch silicon wafers on a spin chuck, and spun at 2500 rpm for 30 seconds. The films were gelled and aged in a vacuum chamber using the following conditions: The chamber was evacuated to −20 inches of Hg. Next, 15M ammonium hydroxide was heated and equilibrated at 45° C. and dosed into the chamber to increase the pressure to −4.0 inches of Hg for 2-3 minutes. Finally, chamber was then evacuated to −20.0 inches of Hg and backfilled with nitrogen. One film was heated at elevated temperatures for 1 min. each at 175° C. and 320° C. in air. The other film was placed in a open hotplate that had been heated and equilibrated to 45° C. The film was left in the chamber for 1 minute then removed and heated at elevated temperatures for 1 min. each at 175° and 320° C. in air. Both films were then inspected by single wavelength multiple angle ellipsometry to determine the refractive index and thickness as seen in Table 5:

TABLE 5
Results of Nanoporous Silica Thin films

| | No low temp | 45° C. low |
|---|---|---|
| | hotplate | temp hotplate |
| Thickness (A) | 3400 | 4100 |
| Refractive index | 1.20 | 1.158 |

This example demonstrates that films treated with a low temperature hotplate shrunk less due to added strength from the heat treatment.

### EXAMPLE 6

This example demonstrates that a nanoporous silica film can be heat treated in a solvent saturated environment to improve the mechanical strength.

A precursor is synthesized by adding 94.0 mL of tetraethoxysilane, 61.0 mL of TriEGMME, 7.28 mL of deionized water, and 0.31 mL of 1N nitric acid together in a round bottom flask. The solution is allowed to mix vigorously then heated to ˜80° C. and refluxed for 1.5 hours to form a solution. After the solution is allowed to cool, it is stored in refrigeration at 4° C. After the solution is allowed to cool, it is diluted 50% by volume with ethanol to reduce the viscosity. The diluted precursor is filtered to 0.1 mm using a teflon filter. Approximately 2.0 ml of the precursor is deposited onto a 4 inch silicon wafer on a spin chuck, and spun at 2500 rpm for 30 seconds.

The film is gelled and aged in a vacuum chamber that is heated and equilibrated to 30° C. The following conditions are used to perform proper aging: The chamber is evacuated to −20 inches of Hg. Next, 15M ammonium hydroxide is heated and equilibrated at 45° C. and dosed into the chamber to increase the pressure to −4.0 inches of Hg for 2-3 minutes. Finally, chamber is then evacuated to −20.0 inches of Hg and backfilled with nitrogen. The film is left in the chamber whereby a nitrogen bubbler flows a >95% saturated gas of TriEGMME heated at 30° C. The film is left in the chamber for 2 minutes then removed and heated at elevated temperatures for 1 min. each at 175° and 320° C. in air. The film is then inspected by single wavelength multiple angle ellipsometry to determine the refractive index and thickness. This example demonstrates that films treated with a heated saturated gas shrinks much less due to added strength from the heat treatment.

### EXAMPLE 7

This example demonstrates that a nanoporous silica film can be heat treated at 50° C. in a solvent saturated environment to improve the mechanical strength.

A precursor is synthesized by adding 94.0 mL of tetraethoxysilane, 61.0 mL of TriEGMME, 7.28 mL of deionized water, and 0.31 mL of 1N nitric acid together in a round bottom flask. The solution is allowed to mix vigorously then heated to ˜80° C. and refluxed for 1.5 hours to form a solution. After the solution is allowed to cool, it is stored in refrigeration at 4° C. After the solution is allowed to cool, it is diluted 50% by volume with ethanol to reduce the viscosity. The diluted precursor is filtered to 0.1 mm using a teflon filter. Approximately 2.0 ml of the precursor is deposited onto a 4 inch silicon wafer on a spin chuck, and spun at 2500 rpm for 30 seconds. The film is gelled and aged in a vacuum chamber that is heated and equilibrated to 50° C. The following conditions are used to perform proper aging: The chamber is evacuated to −20 inches of Hg. Next, 15M ammonium hydroxide is heated and equilibrated at 45° C. and dosed into the chamber to increase the pressure to −4.0 inches of Hg for 2-3 minutes. Finally, chamber is then evacuated to −20.0 inches of Hg and backfilled with nitrogen. The film is left in the chamber whereby a nitrogen bubbler flows a >95% saturated gas of TriEGMME heated at 50° C. The film is left in the chamber for 2 minutes then removed and heated at elevated temperatures for 1 min. each at 175° and 320° C. in air. The film is then inspected by single wavelength multiple angle ellipsometry to determine the refractive index and thickness. This example demonstrates that films treated with a heated saturated gas shrinks much less due to added strength from the heat treatment.

### EXAMPLE 8

This example demonstrates that a nanoporous silica film can be heat treated at 30° C. in a solvent saturated environment to improve the mechanical strength.

A precursor is synthesized by adding 94.0 mL of tetraethoxysilane, 61.0 mL of TriEGMME, 7.28 mL of deionized water, and 0.31 mL of 1N nitric acid together in a round bottom flask. The solution is allowed to mix vigorously then heated to ˜80° C. and refluxed for 1.5 hours to form a solution. After the solution is allowed to cool, it is stored in refrigeration at 4° C. After the solution is allowed to cool, it was diluted 50% by volume with ethanol to reduce the viscosity. The diluted precursor is filtered to 0.1 mm using a teflon filter. Approximately 2.0 ml of the precursor is deposited onto a 4 inch silicon wafer on a spin chuck, and spun at 2500 rpm for 30 seconds. The film is gelled and aged in a vacuum chamber that is heated and equilibrated to 30° C. The following conditions are used to perform proper aging: The chamber is evacuated to −20 inches of Hg. Next, 15M ammonium hydroxide is heated and equilibrated at 45° C. and dosed into the chamber to increase the pressure to −4.0 inches of Hg for 2-3 minutes. Finally, chamber is then evacuated to −20.0 inches of Hg and backfilled with nitrogen. The film is left in the chamber whereby a nitrogen bubbler flows a >95% saturated gas of TriEGMME heated at 30° C. The film is left in the chamber for 1 minute then removed and heated at elevated temperatures for 1 min. each at 175° and 320° C. in air. The film is then inspected by single wavelength multiple angle ellipsometry to determine the refractive index and thickness. This example demonstrates that films treated with a heated saturated gas shrinks much less due to added strength from the heat treatment.

### EXAMPLE 9

This example demonstrates that a nanoporous silica film can be heat treated at 50° C. in a solvent saturated environment to improve the mechanical strength. A precursor is synthesized by adding 94.0 mL of tetraethoxysilane, 61.0 mL of TriEGMME, 7.28 mL of deionized water, and 0.31 mL of 1N nitric acid together in a round bottom flask. The solution is allowed to mix vigorously then heated to ˜80° C. and refluxed for 1.5 hours to form a solution. After the solution is allowed to cool, it is stored in refrigeration at 4° C. After the solution is allowed to cool, it is diluted 50% by volume with ethanol to reduce the viscosity. The diluted precursor is filtered to 0.1 mm using a teflon filter. Approximately 2.0 ml of the precursor is deposited onto a 4 inch silicon wafer on a spin chuck, and spun at 2500 rpm for 30 seconds. The film is gelled and aged in a vacuum chamber that is heated and equilibrated to 50° C. The following conditions are used to perform proper aging: The chamber is evacuated to −20 inches of Hg. Next, 15M ammonium hydroxide is heated and equilibrated at 45° C. and dosed into the chamber to increase the pressure to −4.0 inches of Hg for 2-3 minutes. Finally, chamber is then evacuated to −20.0 inches of Hg and backfilled with nitrogen. The film is left in the chamber whereby a nitrogen bubbler flows a >95% saturated gas of TriEGMME heated at 50° C. The film is left in the chamber for 1 minute then removed and heated at elevated temperatures for 1 min. each at 175° and 320° C. in air. The film is then inspected by single wavelength multiple angle ellipsometry to determine the refractive index and thickness. This example demonstrates that films treated with a heated saturated gas shrinks much less due to added strength from the heat treatment.

What is claimed is:

1. A process for forming a nanoporous dielectric coating on a substrate which comprises:
(a) forming a substantially uniform alkoxysilane gel composition on a surface of a substrate, which alkoxysilane gel composition comprises a combination of at least one alkoxysilane, an organic solvent composition, water, and an optional base catalyst;
(b) heating the substrate for a sufficient time and at a sufficient temperature in an organic solvent vapor atmosphere to thereby condense the gel composition; and then
(c) curing the gel composition to form a nanoporous dielectric coating on the substrate.

2. The process of claim 1 wherein the organic solvent vapor atmosphere contains a relatively low volatility organic solvent which has a boiling point of about 175° C. or higher.

3. The process of claim 2 wherein the organic solvent vapor atmosphere contains a relatively low volatility organic solvent is selected from the group consisting of di(ethylene)glycol monomethyl ether, tri(ethylene)glycol monomethyl ether, tetra(ethylene)glycol monomethyl ether; di(propylene)glycol monomethyl ether, tri(propylene)glycol monomethyl ether, ethylene glycol, 1,4-butylene glycol, 1,5-pentanediol, 1,2,4-butanetriol, 1,2,3-butanetriol, 2-methyl-propanetriol, 2-(hydroxymethyl)-1,3-propanediol, 1,4,1,4-butanediol, 2-methyl-1,3 -propanediol, tetraethylene glycol, triethylene glycol monomethyl ether, glycerol, di(ethylene)glycol, tri(ethylene)glycol, tetra(ethylene)glycol, penta(ethylene)glycol, di(propylene)glycol, hexa(ethylene)glycol and mixtures thereof.

4. The process of claim 1 wherein the organic solvent composition of step (a) comprises the same organic solvent as in the organic solvent vapor atmosphere of step (b).

5. The process of claim 1 wherein the solvent vapor atmosphere contains a relatively low volatility organic solvent which is present in the atmosphere in an amount of from about 50 to about 99.9 percent saturation.

6. The process of claim 1 wherein the optional base catalyst is present in the alkoxysilane gel composition.

7. The process of claim 1 wherein the alkoxysilane gel composition is formed by exposing the alkoxysilane to the water in the form of water vapor.

8. The process of claim 1 wherein the alkoxysilane gel composition is formed by exposing the alkoxysilane to the base catalyst in the form of base vapor.

9. The process of claim 1 wherein the alkoxysilane gel composition is formed by exposing the alkoxysilane both to water in the form of water vapor and to the base catalyst in the form of base vapor.

10. The process of claim 1 wherein the alkoxysilane gel composition is formed by depositing the alkoxysilane and the organic solvent composition onto the substrate in the form of a stream.

11. The process of claim 1 wherein the alkoxysilane gel composition is formed by depositing the alkoxysilane, the organic solvent composition, and the water onto the substrate in the form of a combined stream.

12. The process of claim 1 wherein the alkoxysilane gel composition is formed by depositing the alkoxysilane, the organic solvent composition, and the base catalyst onto the substrate in the form of a combined stream.

13. The process of claim 1 wherein the alkoxysilane gel composition is formed by depositing the alkoxysilane, the organic solvent composition, the water, and the base catalyst onto the substrate in the form of a combined stream.

14. The process of claim 1 wherein the organic solvent composition of step (a) comprises a relatively high volatility solvent and a relatively low volatility solvent.

15. The process of claim 14 wherein the relatively high volatility solvent has a boiling point of about 120° C. or less and the relatively low volatility solvent has a boiling point of about 175° C. or more.

16. The process of claim 14 wherein the relatively high volatility solvent comprises one or more components selected form the group consisting of methanol, ethanol, n-propanol, isopropanol, n-butanol and mixtures thereof and wherein the relatively low volatility solvent composition comprises an alcohol or a polyol.

17. The process of claim 1 wherein the base catalyst is selected from the group consisting of ammonia, primary alkyl amines, secondary alkyl amines, tertiary alkyl amines, aryl amines, alcohol amines and mixtures thereof.

18. The process of claim 1 wherein the alkoxysilane has the formula: 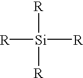
wherein at least 2 of the R groups are independently C₁ to C₄ alkoxy groups and the balance, if any, are independently selected from the group consisting of hydrogen, alkyl, phenyl, halogen, substituted phenyl.

19. The process of claim 18 wherein each R is methoxy, ethoxy or propoxy.

20. The process of claim 1 wherein the alkoxysilane composition comprises at least one organic solvent selected from the group consisting of methanol, ethanol, n-propanol, isopropanol, n-butanol, ethylene glycol, 1,4-butylene glycol, 1,5-pentanediol, 1,2,4-butanetriol, 1,2,3-butanetriol, 2-methyl-propanetriol, 2-(hydroxymethyl)-1,3-propanediol, 1,4,1,4-butanediol, 2-methyl-1,3-propanediol, tetraethylene glycol, triethylene glycol monomethyl ether, glycerol, and mixtures thereof.

21. The process of claim 1 wherein the substrate comprises silicon or gallium arsenide.

22. The process of claim 1 wherein the substrate comprises at least one semiconductor material.

23. The process of claim 21 wherein the semiconductor material is selected from the group consisting of gallium arsenide, silicon, and compositions containing silicon such as crystalline silicon, polysilicon, amorphous silicon, epitaxial silicon, and silicon dioxide, and mixtures thereof.

24. The process of claim 1 wherein the substrate has a pattern of lines on its surface.

25. The process of claim 24 wherein the lines comprise a metal, an oxide, a nitride or an oxynitride.

26. The process of claim 1 wherein the gel composition is cured by heating.

27. The process of claim 1 wherein the nanoporous dielectric coating has a dielectric constant of from about 1.1 to about 3.5.

28. The process of claim 1 further comprising the step, after step (b) and either before or after step (c), of treating the nanoporous dielectric coating with a surface modification agent under conditions sufficient to render the nanoporous dielectric coating hydrophobic.

29. The process of claim 28 wherein the surface modification agent comprises hexamethyldisilazane.

30. The coated substrate formed by the process of claim 1.

31. A semiconductor device produced by a process which comprises:
(a) forming a substantially uniform alkoxysilane gel composition on a surface of a semiconductor substrate, which alkoxysilane gel composition comprises a combination of at least one alkoxysilane, an organic solvent composition, water, and an optional base catalyst;
(b) heating the semiconductor substrate for a sufficient time and at a sufficient temperature in an organic solvent vapor atmosphere to thereby condense the gel composition; and then
(c) curing the gel composition to form a nanoporous dielectric coating on the semiconductor substrate.
